(19) United States
(12) Patent Application Publication
(10) Pub. No.: US 2009/0166684 A1
(43) Pub. Date: Jul. 2, 2009

(54) PHOTOGATE CMOS PIXEL FOR 3D CAMERAS HAVING REDUCED INTRA-PIXEL CROSS TALK

(75) Inventors: Giora Yahav, Haifa (IL); Thomas Reiner, Kirat Motzkin (IL)

Correspondence Address: Dr. Allan C. Entis, Intellectual Property Ltd., 6 Raoul Wallenberg Street, Ramat Hachayal, Tel Aviv, 69719, IL

(73) Assignee: 3DV SYSTEMS LTD., Yokneam (IL)

(21) Appl. No.: 12/344,601

(22) Filed: Dec. 29, 2008

Related U.S. Application Data
(60) Provisional application No. 61/016,607, filed on Dec. 26, 2007.

(51) Int. Cl. H01L 31/101; H01L 31/02

(52) U.S. Cl. 257/225; 257/431; 257/290

(57) ABSTRACT

A CMOS photodetector pixel formed of a substrate, an epitaxial layer above the substrate including a first region having the same polarity but a lower impurity concentration as that of the substrate, and a gate arrangement including a first gate that forms a charge accumulation region in the epitaxial layer when the gate is energized, wherein the charge accumulation region extends deeper toward the substrate than in conventional constructions. The epitaxial layer includes a shielding structure for absorbing electrons generated therein by photons impinging on the pixel, except electrons generated close to the charge accumulation region. The shielding structure may have opposite polarity from that of the substrate, including a first portion under the first gate, and a second portion extending upward from the first portion at the margin of the pixel. Alternatively, the shielding structure may have the same polarity as the substrate, but a lower impurity concentration.

### CROSS-REFERENCES TO RELATED APPLICATIONS

The present application claims benefit under 35 U.S.C. § 119(e) of U.S. Provisional Application 61/016,607 filed Dec. 26, 2007 the entire content of which is incorporated herein by reference.

### BACKGROUND OF THE INVENTION

1. Field of the Invention

This invention relates to image sensors for three-dimensional optical imaging systems, and more particularly to the structure and fabrication of individual image sensing elements for such systems.

2. Relevant Art

Imaging systems capable of providing precise and rapid measurement of surface features of remote objects, referred to below as “3D cameras”, have many uses, including profile inspection of manufactured objects, computerized design verification, robot vision, geographic surveying, object recognition, and control of interactive activities such as computerized games, e.g., to determine the position of a player relative to a computer-generated image.

For applications such as those described, 3D cameras generally include a light source for illuminating an object being inspected, a light sensing array comprised of multiple independent light sensing elements, usually referred to as picture elements or “pixels”, and electronic circuits for processing signals obtained from the pixel array.

Various signal processing schemes are known. One such scheme employs the time-of-flight (TOF) of the reflected light pulses to measure distances from the camera to the surface features of the object being inspected.

Various ways are also known for constructing light sensing arrays and the component pixels, but in many applications, complementary metal oxide semiconductor (or “CMOS”) technology, which is also used for fabrication of the circuitry used in computers and most other digital electronic devices, has emerged as advantageous.

FIG. 1 shows in a cross-sectional view, the structure of a conventional CMOS pixel, generally indicted at 10, constructed as a so-called photogate photodetector as explained in more detail below. As will be appreciated by those skilled in the art, pixel 10 is typically rectangular when viewed from above, and is typically fabricated as part of a two-dimensional array having a plurality of pixels, the number being determined by the desired detail-resolution for the array, together with suitable signal processing circuitry. Standard CMOS fabrication techniques are employed to create the array.

As also known by those skilled in the art, CMOS devices are formed of layers of silicon. Pure silicon is a poor conductor of electricity, so impurities are added, a process generally referred to as “doping”, to obtain desired electrical properties. In particular, doping with a “donor” element such as phosphorous or arsenic creates a material having an excess of electrons that can be made to flow as an electrical current. Such a material is referred to as “N-type”, or as having N-polarity. Doping with an “acceptor” element such as boron yields a material having an excess of “holes” (spaces in the crystal structure able to receive electrons). Such a material is referred to as “P-type” or as having “P-polarity”.

Referring still to FIG. 1, pixel 10 is comprised of a first layer 12, typically formed of P-type silicon, which serves as a substrate. A second layer 14 also formed of P-type silicon but with a lower impurity content than substrate 12, is formed above substrate 12. Layer 14, typically referred to as a “P-well”, is used as the silicon for fabricating various components comprised in pixel 10 as described below. A third layer 16 is formed of an insulating material such as silicon dioxide (referred to below simply as an “oxide layer”).

Directly beneath oxide layer 16, and at the upper end of P-well 14, are formed two so-called N+ “floating diffusions” 18 and 20. (The “N+” designation refers to an especially high level of N-type doping.) These regions are essentially capacitive, i.e., capable of storing electrons, and function in a manner described below. Control of the device is provided by three electrodes or gates 22, 24, and 26, as described in more detail below, typically formed of polycrystalline silicon (“polysilicon”) located on top of oxide layer 16. Polysilicon is characterized by a crystal structure formed of multiple small silicon crystals. Providing an isolation around the upper portion of P-well 14 is a conventional shallow trench isolation area 27 typically formed of silicon dioxide.

The illustrated device functions as a photodetector because photons (individual quantities of light, which may be thought of as particles) reflected from an object under inspection entering pixel 10 create electron-hole pairs in the crystalline structure of the silicon material. A structure such as pixel 10 is generally referred to as a “photogate photodetector” because an electric field (e-field) emanating from gate 22 when a voltage of a proper level is applied creates a “depletion” region 28 in the underlying P-well capable of attracting electrons released by photon impingement. The depletion region starts at the surface of the p-well, and extends toward silicon substrate 12. The depth of the depletion region is a function of gate oxide thickness, gate voltage, P-well doping concentration and P-well doping profile as well as the substrate doping concentration and substrate doping profile. Conventional technology gives a depletion depth of less than 0.5 μm in a p-well having a typical depth of 1.5 μm. Accumulation of charge (electrons) in depletion region 28 gives rise to a voltage that can be measured as an indication of photon impingement. Active devices such as transistor amplifiers (not shown) fabricated within P-well 14 provide signal outputs from pixel 10 for that purpose.

Also illustrated in FIG. 1 is a P-epitaxial (epi) layer 32 between substrate 12 and P-well 14. An epitaxial or epi layer is a thin layer (0.5 to 20 microns) usually formed through chemical vapor deposition (CVD).

When energized, gates 24 and 26 allow electron flow between depletion region 28 and respective floating diffusions 18 and 20, and the resulting charge transferred induces voltages, which can also be measured. By activating gates 24 and 26 at proper times, and measuring the resulting voltages, detection of the leading and trailing portions of the reflected light pulse can be achieved. This gives an indication of the distance to the surface of the object being inspected. Gates 24 and 26 are accordingly referred to as the “front” and “back” gates, respectively. Further details, including examples of how an array of pixels such as pixel 10 may be employed in a 3D camera may be found in the above-mentioned Zigelman et al. patent application.

A problem with a conventional pixel construction as described above is that the location within pixel 10 of electron-hole pair generation resulting from photon impingement is strongly related to the wavelength of the incoming light. In particular, more electrons are generated deeper inside silicon substrate 12 for longer wavelengths. For 3D imaging applications, the light used is often in the near infrared region (wavelengths slightly longer than red light, and invisible to the eye). At such wavelengths, most of the electrons are generated deep inside the silicon. For example, for 850 nm (850×10⁻⁹ meters) wavelength light, about 66% of the reflected photons are absorbed (and electrons are generated) at a depth of about 12 μm or greater from the silicon surface.

When gate 22 is activated, the resulting e-field causes electrons generated nearby to travel to depletion region 28 by a so-called drift field process. This is a relatively-rapid process and is the basis on which the sensor operates. However, electrons generated deep in the silicon substrate 12 are not strongly affected by the e-field, and travel toward the detector surface by a diffusion mechanism. This is a slow process compared to the drift field process, and is not well controlled. Consequently, the upwardly diffusing electrons can travel directly to floating diffusions 18 and 20 with about equal probability causing what is referred to as “intra-pixel cross talk”. This can affect the voltage measurements that are made when front and back gates 24 and 26 are activated, and can cause inaccuracies in detection of the leading and trailing portions of the reflected light pulses.

One known solution is to increase the doping of substrate 12 from a customary value used in conventional CMOS fabrication, e.g., 3e14 cm⁻³ to about 1e19 cm⁻³. This is effective in absorbing electrons generated in substrate 12, but electrons generated above the substrate that are not close enough to gate 22 to be strongly attracted by the e-field in depletion region 28 can still travel by diffusion to front and back gates 24 and 26 and their respective floating diffusions 18 and 20. The P-epitaxial (epi) layer 32 mentioned above is sometimes also added between substrate 12 and P-well 14, either with or without increased doping in substrate 12.

### SUMMARY OF THE INVENTION

Several embodiments of the invention are described below, and other embodiments will be recognized by those skilled in the art from the description herein. Some embodiments of the invention depart from conventional practice by providing a shielding structure comprised of a deep N-well plus a surrounding N-well barrier region within a P-type epi layer formed on a high impurity concentration (P+) substrate.

In such embodiments, electrons generated within the substrate are effectively trapped there by the high level of doping of the substrate, and electrons generated above the substrate, but below the N-well are trapped by the N-well. Some electrons generated in the P epi region immediately above the N-well can also diffuse downward toward the N-well, and be trapped there.

Further, because of the doping of the epitaxial layer itself, the depletion region is able to extend downward almost to the deep N-well. Consequently, the electrons generated by photons impinging under the photo gate either diffuse downward and are trapped by the N-well, or get swept by the drift (electric) field to the nearby depletion region, and the floating diffusions associated with the front and back gates are not affected by the upwardly diffusing electrons.

According to some embodiments of the invention, instead of a deep N-well plus a surrounding N-well barrier region, the shielding structure is in the form of a shallow P epi layer, including a base region located below the photogate, the front and back gates, and the floating diffusions, and a peripheral barrier region surrounding the entire pixel.

According to some embodiments of the invention, the doping of the shallow epi layer allows the depletion region to extend downward nearly to the bottom of the shallow epi layer. Consequently, electrons generated between the bottom of the depletion region and the substrate are either absorbed by the substrate due to diffusion, or are attracted into the depletion region by the e-field generated by the photogate.

Therefore, in accordance with an embodiment of the invention, a CMOS photodetector pixel is provided comprising a substrate having first polarity and impurity concentration, an epitaxial layer formed above the substrate including a first region having the same polarity but a lower impurity concentration than that of the substrate, an oxide layer formed above the epitaxial layer; and a gate arrangement formed on the oxide layer including a first gate, that creates a charge accumulation region beneath itself in the epi layer when energized, wherein the epitaxial layer is so constructed that the charge accumulation region extends deeper below the oxide layer into the epi region than in known constructions.

Optionally, in accordance with such an embodiment of the invention, the charge accumulation region created when the first gate is energized extends downward from the oxide layer for a distance in the range of about 1.5 to 2.0 μm. In accordance with an embodiment of the invention, a CMOS photodetector pixel is provided comprising a substrate having a first polarity and impurity concentration, an epitaxial layer formed above the substrate including a first region having the same polarity but a lower impurity concentration than that of the substrate, an oxide layer formed above the epitaxial layer; and a gate arrangement formed on the oxide layer including a first gate, wherein the epitaxial layer includes a shielding structure having a polarity, impurity concentration and geometry such that it functions to substantially absorb electrons generated in the epitaxial layer by photons impinging on the pixel, except for electrons generated in close enough proximity the first gate that they are attracted by an electric field generated when the first gate is electrically energized .

In such a pixel, the first gate is operable when suitably electrically biased to create a charge accumulation region in the first region of the epitaxial layer, and the gate arrangement further includes second and third gates respectively spaced laterally from the first gate. The pixel further includes first and second floating diffusions which are essentially capacitive within the epitaxial layer respectively on opposite sides of the second and third gates from the first gate, and the second and third gates are operable when suitably electrically biased to provide charge flow paths between the charge accumulation region and the respective first and second floating diffusions. In addition, the shielding structure is operative to substantially prevent electrons generated in the epitaxial layer by photons impinging on the pixel from reaching the and first and second floating diffusions except through the charge flow paths from the charge accumulation region.

Optionally, the first and second diffusions are embedded within respective wells within the epitaxial layer, the wells having the same polarity as the substrate.

Optionally, in such a CMOS photodetector pixel, the shielding structure comprises a first portion located above the substrate having opposite polarity from that of the substrate and a second portion having the same polarity as the first portion that extends upward from the first portion and defines the margin of the pixel.

Optionally, in a CMOS photodetector pixel in which the shielding structure has a polarity opposite to that of the substrate, the first region of the epitaxial layer includes a part located below the first gate in which the impurity concentration is lowered after fabrication.

Optionally, in a CMOS photodetector in which the shielding structure has a polarity opposite to that of the substrate, the first region of the epitaxial layer is comprised of material grown directly on the substrate with a desired lower impurity concentration than that of the substrate.

Optionally, in a CMOS photodetector in which the shielding structure has a polarity opposite to that of the substrate, the center of the first portion of the shielding structure is located at a distance in the range of approximately 1.5 to 3.0 μm below the oxide layer.

Optionally, in a CMOS photodetector in which the shielding structure has a polarity opposite to that of the substrate, the center of the first portion of the shielding structure is located at a distance of approximately 2.0 μm below the oxide layer.

Optionally, in a CMOS photodetector in which the shielding structure has a polarity opposite to that of the substrate, the thickness of the first portion of the shielding structure is in the range of approximately 0.4 to 1.5 μm.

Optionally, in a CMOS photodetector in which the shielding structure has a polarity opposite to that of the substrate, the thickness of the first portion of the shielding structure is approximately 0.8 μm.

In accordance with an embodiment of the invention in which the shielding structure has a polarity opposite to that of the substrate, the thickness of the epitaxial layer between the substrate and the oxide layer is in the range of about 5.0 to 10.0 μm In accordance with an embodiment of the invention, the epitaxial layer includes a shielding structure that is comprised substantially entirely of material having the same polarity as the substrate, but which a different impurity concentration than that of the substrate.

Optionally, in accordance with an embodiment of the invention in which the shielding structure is comprised substantially entirely of material having the same polarity as the substrate, the thickness of the epitaxial layer between the substrate and the oxide layer is in the range of about 2.5 to 3.5 μm. Optionally, in accordance with an embodiment of the invention in which the shielding structure is comprised substantially entirely of material having the same polarity as the substrate, the thickness of the epitaxial layer between the substrate and the oxide layer is about 3.0 μm.

Optionally, in accordance with embodiments of the invention in which the shielding structure is comprised substantially entirely of material having the same polarity as the substrate, the impurity concentration of the epitaxial layer may be about 1e15 cm⁻³. Further optionally, in accordance with embodiments of the invention in which the shielding structure is comprised substantially entirely of material having the same polarity as the substrate, the properties of the epitaxial layer are such that a charge accumulation region created when the first gate is energized extends downward from the oxide layer for a distance in the range of about 1.5 to 2.0 μm.

### BRIEF DESCRIPTION OF THE DRAWINGS

Non-limiting examples of embodiments of the invention are described below with reference to figures attached hereto that are listed following this paragraph. Identical structures, elements or parts that appear in more than one figure are generally labeled with a same numeral in all the figures in which they appear. Dimensions of components and features shown in the figures are chosen for convenience and clarity of presentation and are not necessarily shown to scale.

FIG. 1 is a cross-sectional view of a photogate photodetector pixel of known construction sometimes used in 3D cameras and conventional CMOS fabrication techniques.

FIG. 2 is a cross-sectional view of a photogate photodetector pixel according to one embodiment of the present invention.

FIG. 3 is a top plan view of the photogate photodetector pixel of FIG. 2.

FIG. 4 is a cross-sectional view of a photogate photodetector pixel according to a variation of the first embodiment of the present invention.

FIG. 5 is a cross-sectional view of a photogate photodetector pixel according a second embodiment of the present invention.

In the drawings, like parts are identified by like reference numerals.

### DETAILED DESCRIPTION

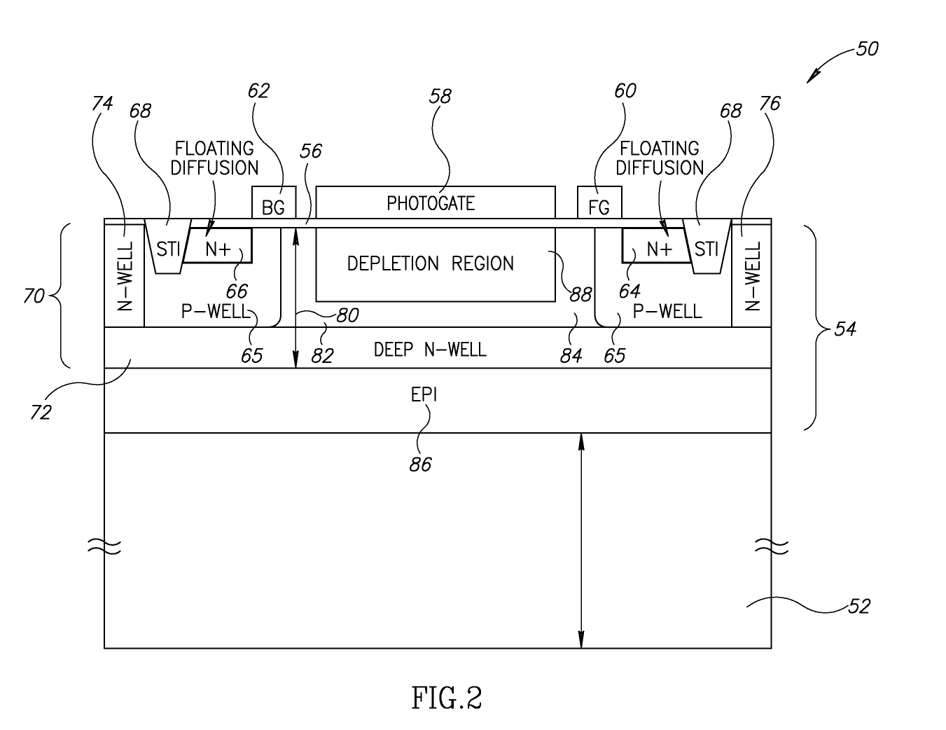

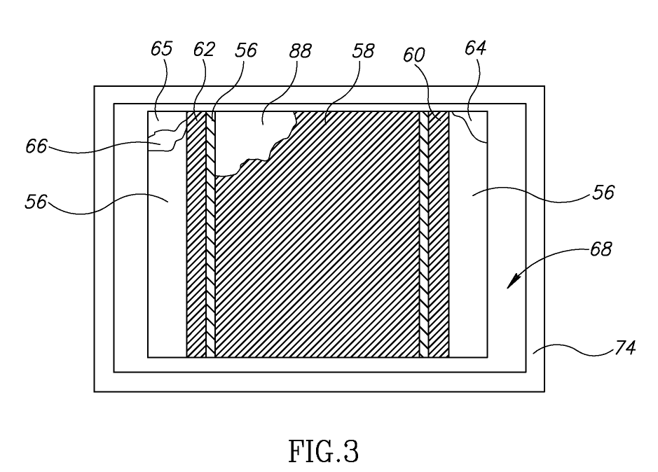

FIGS. 2 and 3 are cross sectional and plan views of a photodetector pixel according to an embodiment of the invention, generally denoted 50. Pixel 50 comprises a P+ type substrate layer 52, a P-epitaxial (or “epi”) layer 54 on substrate 52, and an oxide layer 56 formed on epi layer 54. A polysilicon photogate 58 is formed centrally on oxide layer 56, and front and back gates 60 and 62, also comprised of polysilicon, are formed, optionally, as elongated strips laterally spaced from photogate 58 along oxide layer 56. A P-well 65 is implanted within epi layer 54 and forms a border surrounding photogate 58. Floating diffusions 64 and 66 are formed beneath oxide layer 56, at the upper end of epi layer 54 in P-well 65 laterally outward from front and back gates 60 and 62 respectively. A shallow trench isolation region 68 formed in P-well 65 surrounds gates 58, 60, and 62, and diffusions 64 and 66. (Portions of oxide layer 56 overlying diffusions 64 and 66, and shallow trench isolation region 68 and a portion of diffusion 66 have been cut away in FIG. 3 for clarity.) Substrate 52 has a thickness in the range of about 500 μm to about 850 μm, e.g., 800 μm. However, the doping concentration of substrate 52 is about 1e19 cm⁻³. This is substantially above the conventional concentration (e.g., about 5e14 cm³ as discussed above), and aids in effective absorption of electrons generated within the substrate. P-well 65 is doped to a concentration in the range of about 5e16 cm⁻³ to about 5e17 cm⁻³, e.g., 1e17 cm³

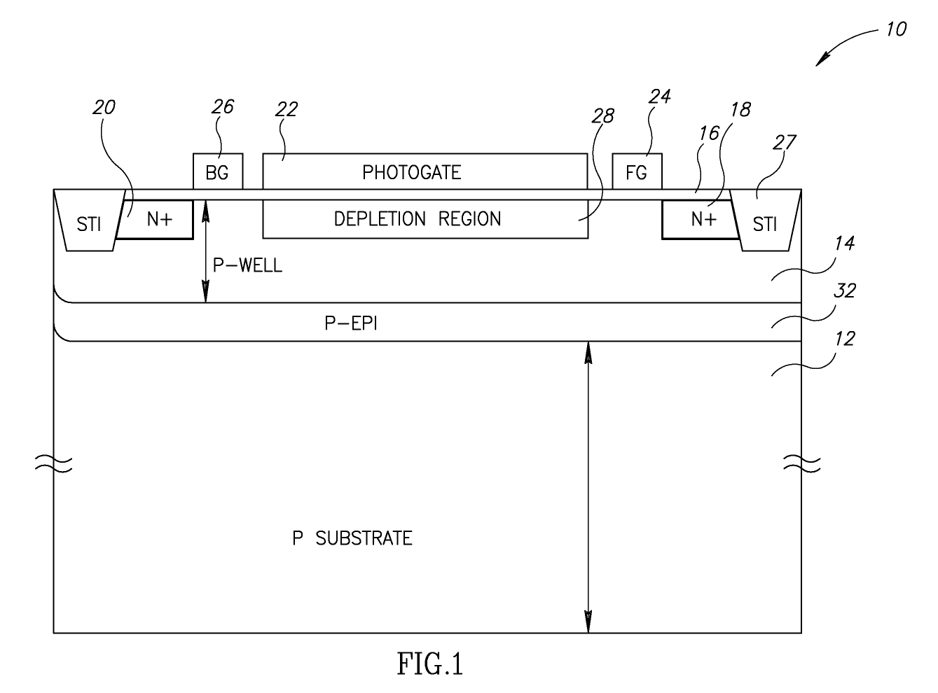

As in the case of the photodetector pixel 10 shown in FIG. 1, activation of photogate 58 creates a depletion region 88 which accumulates electrons resulting from impingement of reflected photons on the silicon structure, and activation of front and back gates 60 and 62 permits charge transfer to floating diffusions 64 and 66.

According to an embodiment of the invention, it has been found that implanting a shielding structure in the form of an N-type deep well within epi structure 54 can significantly reduce the effects of intra-pixel cross talk. Accordingly, epi structure 54 includes a shielding structure 70 formed of a first deep N-well portion 72 and a peripheral barrier portion 74 extending upward from deep N-well portion 72 to the underside of oxide layer 56. As illustrated in FIG. 3, N-type barrier portion 74 provides a peripheral wall completely surrounding shallow trench isolation region 68, gates 58, 60, and 62, and diffusions 64 and 66. Similarly, deep N-well portion 72 forms a barrier extending completely under shallow trench isolation region 68, gates 58, 60, and 62, and diffusions 64 and 66, as well as an upper portion 82 of epi layer 54.

The geometry, location, and doping of the deep N-well portion 72 and of the peripheral barrier region 74 provide effective absorption of electrons generated within the lower portion 86 of epi layer 54. Even directly under photogate 58, the lower portion 86 of epi layer 54 is far enough away from photogate 58 so that electrons generated there are not substantially attracted to depletion region 88 created when gate 58 is activated. These electrons are absorbed by deep N-Well 70, and therefore do not affect the voltages measured when front and back gates 60 and 62 are activated.

As will be appreciated, charge accumulation in deep N-well portion 72 and peripheral barrier region 74 is prevented by connecting the N material to a suitable positive voltage. This connection may be made in any desired and suitable manner.

As a non-limiting example, for the embodiment of FIGS. 2 and 3, epitaxial region 54 may have a thickness in the range of 5.0-10 μm, Deep N-well portion 72 may have a thickness in the range of about 0.4 to 1.5 μm, nominally, 0.8 μm, and a depth to its center (indicated by arrow 80) in the range of about 1.5 to 3.0 μm, nominally, 2.0 μm. It should, however, be understood that the dimensions stated above are by way of example only, and that other dimensions for Deep N-well 72 that can provide the necessary absorption of upwardly diffusing electrons and isolation for depletion region 88 and diffusions 64 and 66 are also within the scope of the invention.

It should also be noted that depletion region 88 is not formed in a P-well as in the conventional practice illustrated in FIG. 1, but within epi layer portion 84. It is therefore subject only to the doping of the epi layer. Consequently, the depletion region can extend downward into epi region 82 just above deep N-well portion 72 almost to the deep N-well portion 72, e.g. to a depth of about 1.5-3.0 μm below oxide layer 56. Thus nearly all the electrons originating under the photo gate 58 gets swept by the drift (electric) field to the nearby depletion region, except for some small number which originate so close to the surface of N-well portion 72 that they diffuse downward into the N-well.

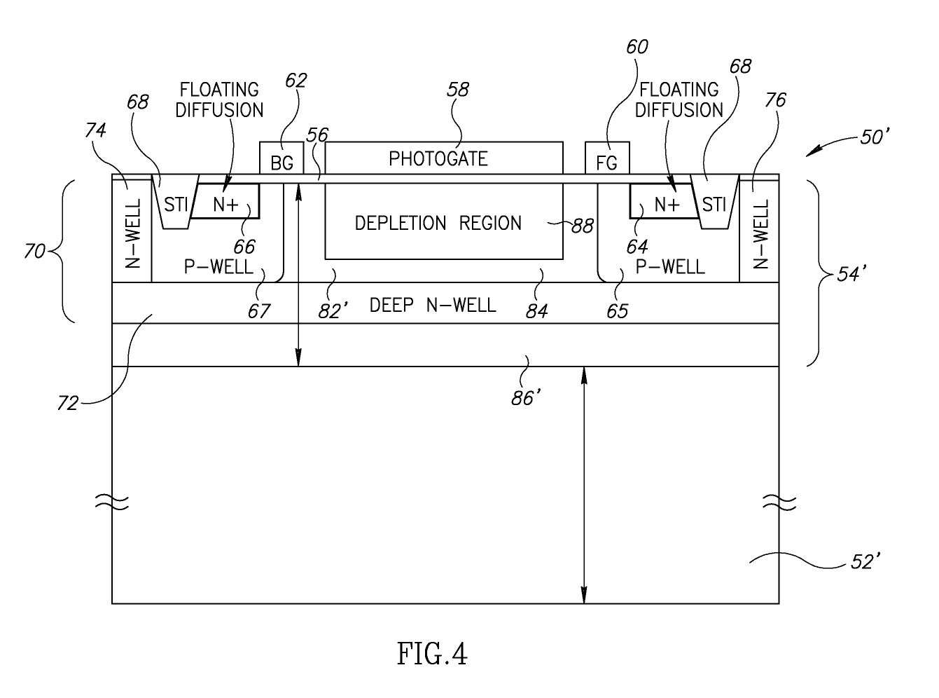

A variation of the first embodiment is illustrated in FIG. 4. Here, a pixel 50′ is similar to pixel 50 shown in FIG. 2, but the P-portions of an epi-layer 54′ are formed with a lower doping concentration that that of epi-layer 54 shown in FIG. 2. Apart from the geometric and dimensional features discussed above in connection with FIGS. 2 and 3, it has been found that improvement of the isolation provided by N-well bottom portion 72 can be obtained by reducing the doping concentration of the P-type portions of epitaxial layer 54 below the values normally employed. For example, in the structure illustrated in FIG. 4, the doping concentration of P-portion 82′ of epi-layer 54′ may be reduced from about 5e14 cm⁻³ employed in epi layer 54 to about 1e14 cm⁻³, e.g., by counter-doping the epitaxial area under photogate 58 using ion implantation techniques, whereby the depletion region (i.e., the effect of the e-field created when photogate 58 is energized) can be made to extend even further down toward N-well portion 72. Consequently, virtually none of the electrons generated just above N-well 72 are likely to diffuse upwardly toward floating diffusions 64 and 66, and more likely to be attracted to depletion region 88.

Counter-doping of region 84 of epi-layer 54′ under photogate 58 can be done using a special implantation of phosphorous ions by means of a special mask. An alternative technique is to grow the entire P-type portion of epi-layer 54′ with a desired reduced concentration initially. Either method may be employed in conjunction with the deep N-well described above. Any other suitable and desired method may also be employed, as will be understood by those skilled in the art in light of the disclosure herein.

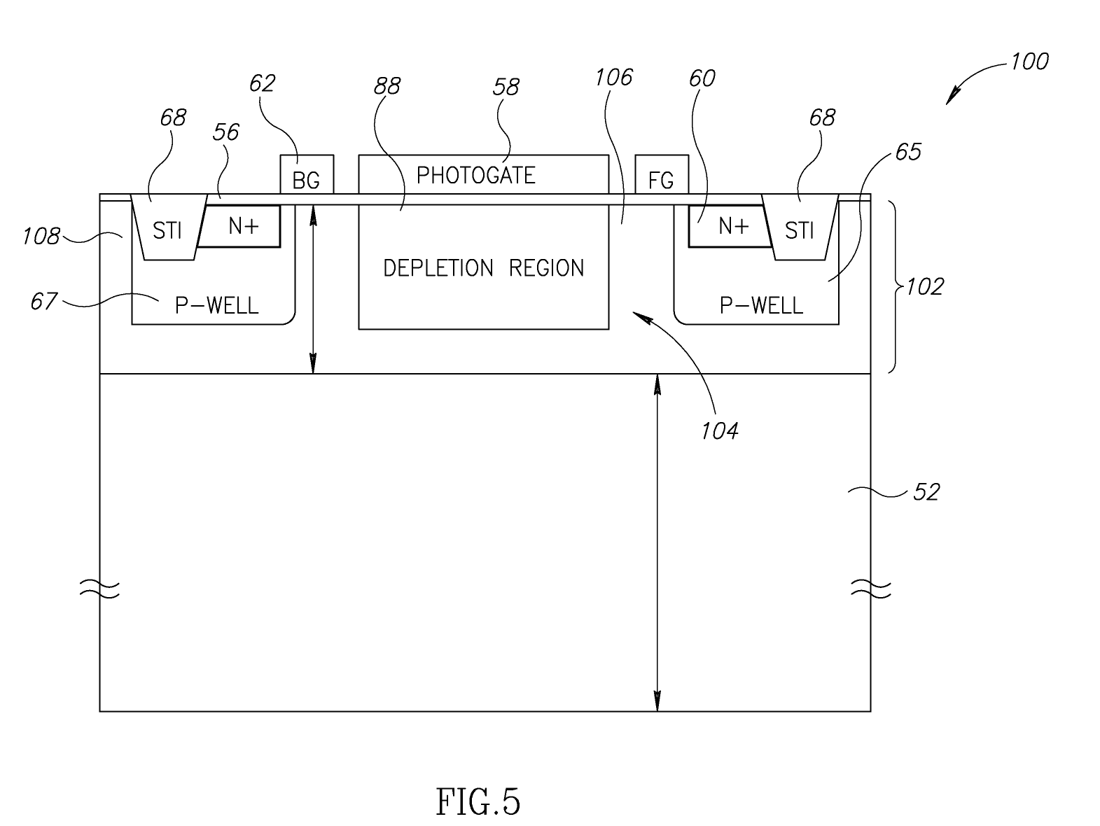

The embodiment illustrated in FIGS. 2-4 is advantageous in that apart from the effective elimination of intra-pixel cross talk, the structure behaves like other CMOS devices. However, fabrication is somewhat more complex and costly. When this is a consideration, and possible variation from conventional CMOS operation can be tolerated, a construction that can be fabricated more simply may optionally be employed, as illustrated in the embodiment of FIG. 5. Here, a pixel, generally indicated at 100, includes an epi-layer 102 which is formed of a P-type material body 104, with embedded floating diffusions 64 and 66, P-wells 65 and 67 and a surrounding shallow trench isolation structure 68 as previously described. Oxide layer 56 and gates 58, 60 and 62 are also as in the embodiment of FIGS. 2-4. However, the underlying deep N-well and N-type peripheral barrier portion of the embodiment of FIGS. 2-4 is not employed.

Body 104 of epi-layer 102 includes a lower shielding structure 106 within which depletion region 88 is formed by activation of gate 58, and an outer peripheral barrier portion 108. Preferably, epi-layer 102 is thinner than in the first embodiment, with a thickness in the range of about 2.5 to 4.0 μm, nominally 3.0 μm. The doping concentration may be in the range of about 3e14-5e15 cm⁻³, nominally, 1e15 cm⁻³.

With the structure described, depletion region 88 can also extend closer to substrate 52, e.g., to a depth of about 1.5 to 2.0 μm. This assures that substantially all elections generated above substrate 52 and below photogate 52 are attracted to the depletion region 88 and reach floating diffusions 64 and 66 only through the electron flow paths from depletion region 88 when front and back gates 60 and 62 are energized.

In general, although the present invention has been described in relation to specific embodiments and variations thereof, many other variations and modifications and other uses will become apparent to those skilled in the art. It is intended, therefore, that the present invention not be limited by the specific disclosure herein, but is to be given the full scope permitted by the appended claims.

1. A CMOS photodetector pixel comprising:
a substrate having first polarity and impurity concentration;
an epitaxial layer formed above the substrate including a first region having the same polarity but a lower impurity concentration from that of the substrate;
an oxide layer formed above the epitaxial layer; and
a gate arrangement formed on the oxide layer including a first gate,
wherein the epitaxial layer includes a shielding structure having a polarity, impurity concentration and geometry such that it functions to substantially absorb electrons generated in the epitaxial layer by photons impinging on the pixel, except for electrons generated in close enough proximity to the first gate as to be attracted by an electric field generated when the first gate is electrically energized.

2. A CMOS photodetector pixel according to claim 1, wherein the first and second diffusions are embedded within respective wells within the epitaxial layer, the wells having the same polarity as the substrate.

3. A CMOS photodetector pixel as according to claim 1 wherein the shielding structure of the epitaxial layer comprises:
a first portion located above the substrate having opposite polarity from that of the substrate; and
a second portion having the same polarity as the first portion that extends upward from the first portion and defines the margin of the pixel.

4. A CMOS photodetector pixel according to claim 1 wherein the first gate is operable when suitably electrically biased to create a charge accumulation region in the first region of the epitaxial layer; wherein the gate arrangement further includes second and third gates respectively spaced laterally from the first gate; and further including:
first and second floating essentially capacitive diffusions within the epitaxial layer respectively on opposite sides of the second and third gates from the first gate, the second and third gates being operable when suitably electrically biased to provide charge flow paths between the charge accumulation region and the respective first and second floating diffusions;
the shielding structure of the epitaxial layer being operative to substantially prevent electrons generated in the epitaxial layer by photons impinging on the pixel from reaching the and first and second floating diffusions except through the charge flow paths from the charge accumulation region.

5. A CMOS photodetector pixel according to claim 3 wherein the first region of the epitaxial layer includes a part located below the first gate in which the impurity concentration is lowered after fabrication.

6. A CMOS photodetector pixel according to claim 3 wherein the first region of the epitaxial layer includes a part located below the first gate in which the impurity concentration is lowered by counter-doping after fabrication to a value of approximately 1e14 cm⁻³.

7. A CMOS photodetector pixel according to claim 3 wherein the first region of the epitaxial layer is comprised of material grown on the substrate with an impurity concentration of about 1e 14 cm⁻³.

8. A CMOS photodetector according to claim 3 wherein the center of the first portion of the shielding structure is located approximately 2 μm below the oxide layer.

9. A CMOS photodetector according to claim 3 wherein the center of the first portion of the shielding structure is located approximately in the range of about 1.5 to about 3.0 μm below the oxide layer.

10. A CMOS photodetector according to claim 3 wherein the thickness of the first portion of the shielding structure is in the range of about 0.4 to about 1.5 μm.

11. A CMOS photodetector according to claim 3 wherein the thickness of the first portion of the shielding structure is about 0.8 μm.

12. A CMOS photodetector according to claim 1 wherein the thickness of the epitaxial layer is in the range of about 5.0 to about 10.0 μm.

13. A CMOS photodetector according to claim 4 wherein the depth of the charge accumulation region in the epitaxial layer is in the range of about 1.5 to about 2.0 μm.

14. A CMOS photodetector according to claim 1 wherein the shielding structure is comprised substantially entirely of material having the same polarity as the substrate, but having a lower impurity concentration than that of the substrate.

15. A CMOS photodetector according to claim 1 wherein the thickness of the epitaxial layer between the substrate and the oxide layer is in the range of about 2.5 to about 4.0 μm.

16. A CMOS photodetector according to claim 1 wherein the thickness of the epitaxial layer between the substrate and the oxide layer is about 3.0 μm.

17. A CMOS photodetector according to claim 1 wherein the impurity concentration of the shielding structure is about 1e15 cm⁻³.

18. A CMOS photodetector according to claim 1 wherein a charge accumulation region is formed in the epitaxial layer when the first gate is energized, and which extends downward from the oxide layer toward the substrate a distance in the range of about 1.5 to about 2.0 μm.

19. A CMOS photodetector pixel according to claim 14 , wherein the first gate is operable when suitably electrically biased to create a charge accumulation region in the first region of the epitaxial layer; wherein the gate arrangement further includes second and third gates respectively spaced laterally from the first gate;
and further including:
first and second floating essentially capacitive diffusions within the epitaxial layer respectively on opposite sides of the second and third gates from the first gate, the second and third gates being operable when suitably electrically biased to provide charge flow paths between the charge accumulation region and the respective first and second floating diffusions;
the shielding structure of the epitaxial layer being operative to substantially prevent electrons generated in the epitaxial layer by photons impinging on the pixel from reaching the and first and second floating diffusions except through the charge flow paths from the charge accumulation region.

20. A photodetector comprising pixels formed in a semiconductor substrate, each pixel comprising:
a photogate for controlling a depletion region in the substrate under the photogate;
diffusion regions on either side of the depletion region;
gates on either side of the photogate for controlling electric fields between the depletion region and the diffusion regions; and
a substantially electrically conductive boundary region in the substrate that contains the depletion and diffusion regions.
